(19) United States
(12) Patent Application Publication
(10) Pub. No.: US 2024/0294196 A1
(43) Pub. Date: Sep. 5, 2024

(54) OVERHEAD HOIST TRANSPORT SYSTEM

(71) Applicant: Samsung Electronics Co., Ltd., Suwon-si (KR)

(72) Inventors: Hyunjae Kang, Suwon-si (KR); Seunggyu Kang, Suwon-si (KR); SANGMIN KIM, Suwon-si (KR); JAESUNG BYUN, Suwon-si (KR); YONG-JUN AHN, Suwon-si (KR); MIN KYUN LEE, Suwon-si (KR); SANGKYUNG LEE, Suwon-si (KR); HYUNWOO LEE, Suwon-si (KR); JEONGHUN LIM, Suwon-si (KR); JUNHYUK CHANG, Suwon-si (KR)

(21) Appl. No.: 18/377,782

(22) Filed: Oct. 7, 2023

(30) Foreign Application Priority Data
Mar. 3, 2023 (KR) 10-2023-0028650

(51) Int. Cl. B61F 5/52; B61C 9/50; B61F 5/06; B66C 7/02; B66C 7/08

(52) U.S. Cl. CPC B61F 5/52; B61C 9/50; B61F 5/06; B66C 7/02; B66C 7/08

(57) ABSTRACT

An embodiment of the present disclosure provides an overhead hoist transport system including: a driving rail configured to extend in a first direction; a support rail positioned parallel to the driving rail; and a crane movably connected to the driving rail and the support rail and configured to move along the driving rail and the support rail, wherein the crane includes: a base configured to extend in a second direction perpendicular to the first direction to cross the driving rail and the support rail; a driving wheel connected to the base and configured to move along the driving rail; and a guide wheel connected to the base and pressed toward a contact surface of the support rail to remain in contact with the support rail, the contact surface being a surface in contact with the guide wheel.

### CROSS-REFERENCE TO RELATED APPLICATION

This application claims priority to and the benefit of Korean Patent Application No. 10-2023-0028650, filed in the Korean Intellectual Property Office on Mar. 3, 2023, the entire contents of which are herein incorporated by reference.

### BACKGROUND OF THE DISCLOSURE

### 1. Field of the Disclosure

An aspect of the present disclosure relates to an overhead hoist transport system.

### 2. Description of the Related Art

As production of semiconductors increases, a storage capacity of storage facilities for storing logistics in a factory where semiconductors are fabricated is becoming insufficient. As semiconductor production of the factory continues to increase, shortage of storage capacity continues to rise every year.

When expanding storage facilities in the factory to address the issue of insufficient storage capacity, it leads to a reduction in the available space for installing semiconductor production equipment, ultimately negatively impacting the productivity of semiconductor production.

In order to address this problem, a ceiling type storage device using an overhead hoist transport (OHT) system is being considered.

In general, the overhead hoist transport system includes a crane traveling along a rail extending along a ceiling of a factory, and a long rail may be bent or deformed due to various factors such as installation and processing errors. For example, if the rail is deformed and its straightness is compromised, it can lead to a snake-like motion of the crane or result in insufficient stopping precision.

The rail extending along the ceiling may include multiple rail parts (such as rail pieces) connected with each other, but installation and processing errors between these parts may create steps in the rail. These steps may cause the crane to be detached from the rail.

### SUMMARY OF THE DISCLOSURE

One aspect of the present disclosure has been made in an effort to provide an overhead hoist transport system capable of preventing abnormal driving of a crane due to deformation or error of a rail and increasing driving straightness and stopping accuracy.

According to an embodiment of the present disclosure, an overhead hoist transport system includes a driving rail extending in a first direction, a pair of support rails extending in the first direction and being spaced apart from each other in a second direction perpendicular to the first direction, wherein the driving rail is disposed in a space between the pair of support rails, and a crane movably connected to the driving rail and the support rail and configured to move along the driving rail and the support rail. The crane includes a base extending lengthwise in the second direction and crossing the driving rail and the pair of support rails, a driving wheel connected to the base and configured to move along the driving rail, and a pair of guide wheels connected to the base and configured to be pressed toward contact surfaces of the pair of support rails using an elastic force. The pair of guide wheels contact the pair of support rails by the elastic force. The contact surfaces are surfaces contacting the pair of guide wheels.

According to an embodiment of the present disclosure, an overhead hoist transport system includes a driving rail extending in a first direction, a pair of support rails extending in the first direction and being spaced apart from each other in a second direction perpendicular to the first direction, wherein the driving rail is disposed in a space between the pair of support rails, and a crane movably connected to the driving rail and the support rail and configured to move along the driving rail and the support rail. The crane includes a base extending lengthwise in the second direction and crossing the driving rail and the pair of support rails, a driving wheel connected to the base and configured to move along the driving rail, a bogie including at least one bogie shaft, wherein the bogie is configured to tilt about the at least one bogie shaft, and a support connected to the base and the bogie and configured to tilt about the at least one bogie shaft. The support includes a pair of guide wheels configured to move along the pair of support rails. The pair of guide wheels are configured to be pressed toward the pair of support rails to maintain contact between the pair of support rails and the pair of guide wheels.

According to an embodiment of the present disclosure, an overhead hoist transport system includes first and second support rails provided along a ceiling in a factory and extending parallel to each other in a first direction, a driving rail positioned between the first support rail and the second support rail, and a crane movably connected to the first support rail, the second support rail, and the driving rail to move along the first support rail, the second support rail, and the driving rail. The crane includes a base extending lengthwise in a second direction perpendicular to the first direction and crossing the first support rail, the second support rail, and the driving rail, wherein the base includes an auxiliary rail extending in the second direction, a carriage movably connected to the auxiliary rail and configured to move in a third direction perpendicular to the first and second directions, a driving wheel connected to the base and configured to move along the driving rail, and a support including a bogie including at least one bogie shaft and connected to the base and a pair of guide wheels connected to the bogie and configured to be tiltable about the at least one bogie shaft and move along the first support rail and the second support rail, respectively. The pair of guide wheels are configured to be pressed toward the first support rail and the second support rail to maintain contact with the first support rail and the second support rail, respectively.

### BRIEF DESCRIPTION OF THE DRAWINGS

FIG. 1 illustrates a perspective view of an overhead hoist transport system according to an embodiment.

FIG. 2 illustrates a top plan view of an overhead hoist transport system according to an embodiment.

FIG. 3 illustrates a cross-sectional view in a direction A-A of FIG. 2.

FIG. 4 illustrates an enlarged view of a portion B of FIG. 3.

FIG. 5 illustrates a support in a crane of an overhead hoist transport system according to an embodiment.

FIG. 6 and FIG. 7 each illustrate a view for describing an operation of a support in a crane of an overhead hoist transport system according to an embodiment.

FIG. 8 to FIG. 10 illustrate various modifications of the support.

### DETAILED DESCRIPTION

The present disclosure will be described more fully hereinafter with reference to the accompanying drawings, in which embodiments of the disclosure are shown. The described embodiments may be modified in various different ways, all without departing from the spirit or scope of the present disclosure.

To clearly describe the present disclosure, parts that are irrelevant to the description in the drawings may be omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Hereinafter, an overhead hoist transport system according to an embodiment will be described with reference to drawings.

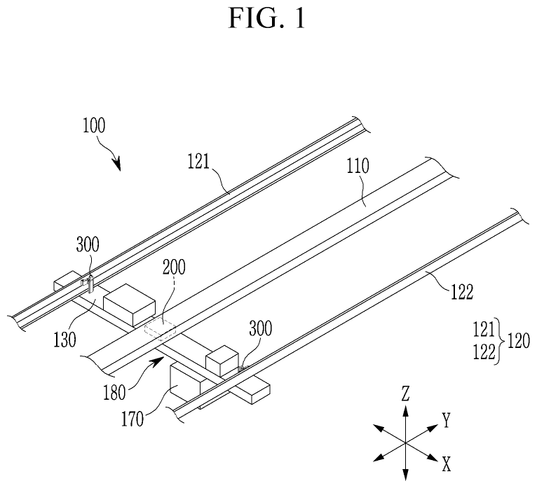

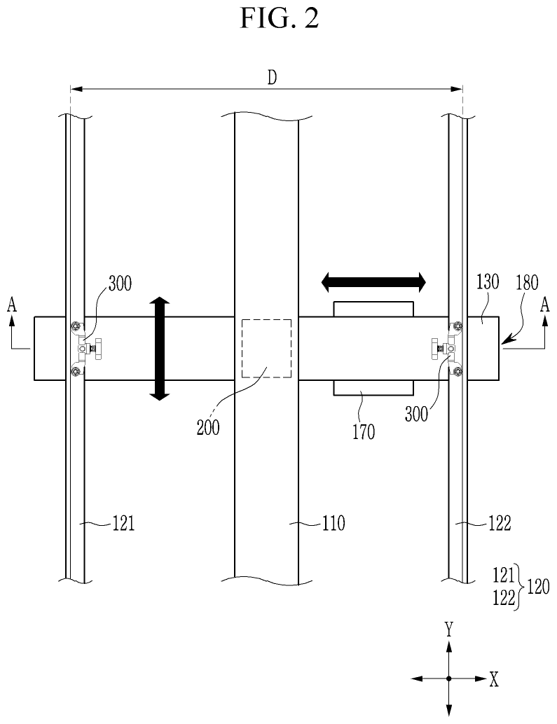

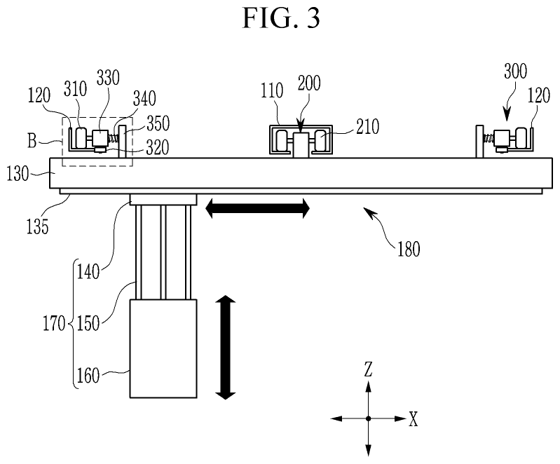

FIG. 1 illustrates a perspective view of an overhead hoist transport system according to an embodiment, FIG. 2 illustrates a view of an overhead hoist transport system according to an embodiment, and FIG. 3 illustrates a cross-sectional view in a direction A-A of FIG. 2.

An overhead hoist transport (OHT) system is a facility for transporting goods in a factory and loading/unloading the goods in a storage facility (not illustrated) by using an overhead hoist crane moving along a rail provided along a ceiling in the factory. Specifically, for the overhead hoist transport system installed within the factory, the transportation of wafers (or front opening unified pods (FOUPs) containing wafers) demands avoiding external impacts and shocks during a crane operation to avoid damage to the wafers. Ensuring stability and precise running and stopping are desirable to avoid such damage to the wafers. The overhead hoist transport system 100 according to an embodiment described below is configured to maintain contact with a rail even when the rail is deformed or misaligned, and thus, it is possible to secure work stability during loading and unloading of goods by preventing abnormal running of the crane and securing the precision of running and stopping.

Referring to FIG. 1, the overhead hoist transport system 100 according to an embodiment includes a driving rail 110, a support rail 120, and a crane 180.

The driving rail 110 extends along a first direction (e.g., a Y direction in FIG. 1). The driving rail 110 may extend adjacent to and along a ceiling (not illustrated). A driving wheel 210 of the crane 180, which will be described later, may be moved along the driving rail 110, and thus the driving rail 110 may guide the crane 180 to travel in a first direction.

The driving rail 110 may include a supportive surface for the driving wheel 210, and the driving wheel 210 may contact the supportive surface of the driving rail 110. For example, the support rail 120 may include a horizontal surface (e.g., a surface parallel to an XY plane or a surface perpendicular to a Z direction in FIG. 1 to FIG. 3).

The driving rail 110 may have a shape surrounding the driving wheel 210 to prevent the driving wheel 210 from being separated from the driving rail 110. For example, the driving rail 110 may have a hollow channel shape with an empty inside, and may have a ‘C’ shaped cross-section as illustrated in FIG. 3. However, a shape of the driving rail 110 is not limited thereto.

As illustrated in FIG. 1 to FIG. 3, the driving rail 110 may be formed in a singular number, but the present disclosure is not limited thereto. As another embodiment, the driving rail 110 may include a plurality of rails parallel to each other. For the sake of clarity and ease of understanding, this description provides an example where the overhead hoist transport system of the embodiment has a single driving rail 110.

The support rail 120 may be positioned parallel to the driving rail 110. For example, the support rail 120 may extend in the first direction (Y direction in FIG. 1). Similar to the driving rail 110, it may extend adjacent to and along a ceiling (not illustrated). A support wheel 310 or a guide wheel 320 of the crane 180, which will be described later, may be moved along the support rail 120, and thus the support rail 120 may guide the crane 180 to travel in the first direction.

The support rail 120 may include a pair of rails. Referring to FIG. 1 and FIG. 2, the support rail 120 may include a first support rail 121 and a second support rail 122 positioned parallel to each other. According to an embodiment, the first support rail 121 and the second support rail 122 may be arranged with the driving rail 110 therebetween. For example, the driving rail 110 may be positioned between the first support rail 121 and the second support rail 122. The following description of the support rail 120 will be made with reference to one specific support rail. However, the same principles can be applied to both the first support rail 121 and the second support rail 122, and the reference numeral 120 will be used to represent the first and second support rails 121 and 122 collectively.

The support rail 120 may include a first surface. The support wheel 310 of the crane 180, which will be described later, can contact the first surface, and be supported by the first surface. For example, the support rail 120 may include a horizontal surface (e.g., a surface parallel to an XY plane or a surface perpendicular to a Z direction in FIG. 1 to FIG. 3).

The support rail 120 may include a second surface on which the guide wheel 320 of the crane 180, which will be described later, can contact and be supported. For example, the support rail 120 may include a vertical surface (e.g., a surface parallel to an YZ plane or a surface perpendicular to an X direction in FIG. 1 to FIG. 3).

The support rail 120 may have a shape including both of the aforementioned two surfaces (first and second surfaces) perpendicular to each other. For example, the support rail 120 may have an ‘L’ shaped cross-section as illustrated in FIG. 3.

The driving rail 110 and the support rail 120 as described above may be spaced apart from a ceiling of a factory by a predetermined interval, and may be fixed to a structure such as a ceiling through a separate support member (not illustrated).

The crane 180 may be movably connected to the driving rail 110 and the support rail 120 in a direction (first direction) in which the driving rail 110 and the support rail 120 extend. That is, the crane 180 may move along the driving rail 110 and the support rail 120. According to an embodiment, the crane 180 may be movably connected to the first support rail 121, the second support rail 122, and the driving rail 110 to move along the first support rail 121, the second support rail 122, and the driving rail 110, respectively.

Referring to FIG. 1 to FIG. 3, the crane 180 may include a base 130, a driver 200, a support 300, and a transport unit 170.

The base 130, which is a body portion of the crane 180, may have a shape crossing the driving rail 110 and the support rail 120. For example, the base 130 may have a shape extending in the X direction that is perpendicular to the Y direction. The X direction and Y direction are shown in FIGS. 1 to 3. For example, the base 130 may be of a bar shape that extends lengthwise in the X direction. The base 130 may have a flat shape, and a distribution panel for operating the crane, various parts, etc. may be installed inside and outside of the base 130. Hereinafter, the X direction and the Y direction may be referred to as a second direction and a first direction, respectively.

The base 130 may be connected to the driving rail 110 and the support rail 120 through the driver 200 and the support 300, respectively. According to an embodiment, a central portion of the base 130 may be connected to the driving rail 110, and opposite end portions thereof may be connected to a pair of first and second support rails 121 and 122, respectively.

The base 130 may include an auxiliary rail 135 extending in the second direction perpendicular to the first direction, which is an elongation direction of the driving rail 110 and the support rail 120. The transport unit 170, which will be described below, may be connected to the base 130 to be movable in the second direction along the auxiliary rail 135. The auxiliary rail 135 may have a shape similar to that of the aforementioned driving rail 110 or support rail 120, but the present disclosure is not limited thereto, and may have various shapes capable of guiding the movement of the transport unit 170 in the second direction.

The driver 200 is a portion that provides a driving force for driving the crane 180 along the driving rail 110. The driver 200 may include a driving wheel 210 and a driving motor (not illustrated) providing a driving force to the driving wheel 210.

According to an embodiment, the driver 200 may be provided above the base 130. For example, when the driving rail 110 is disposed between the pair of first and second support rails 121 and 122, the driver 200 may be positioned at the central portion of the base 130. Meanwhile, the support 300, which will be described later, may be positioned at opposite end portions above the base 130. For example, referring to FIG. 1 to FIG. 3, the support 300 may be symmetrically positioned at opposite sides of the driver 200.

The driving wheel 210 may be rotatably supported on the base 130. The driving wheel 210 may contact a first surface of the driving rail 110, and may be moved on the first surface of the driving rail 110 by receiving a rotational force through a driving motor. The crane 180 may travel along the driving rail 110 by driving the driving wheel 210.

According to an embodiment, the driving wheel 210 may be rotated about an axis parallel to the base 130, that is, the second direction (X direction in FIG. 1 to FIG. 3).

The support 300 is a portion that guides a driving route of the crane 180. That is, the support 300 may guide the crane 180 to move along a straight line along which the linear driving rail 110 and the support rail 120 extend.

According to an embodiment, the support 300 may be positioned at opposite ends of the base 130. For example, when the support rail 120 includes the first and second support rails 121 and 122 with the driving rail 110 therebetween, the support 300 may be symmetrically positioned at opposite ends of the base 130 with respect to the aforementioned driver 200.

The support 300 may include a guide wheel 320 that is supported and rotated while contacting the support rail 120. The guide wheel 320 may contact the support rail 120 without having its own driving force.

According to an embodiment, the guide wheel 320 may maintain contact with a first surface of the support rail 120 in operation of the crane 180. The guide wheel 320 may be configured to be pressed toward the first side of the support rail 120 in operation of the crane 180. Accordingly, even if the support rail 120 does not maintain a straight shape and is deformed or a step is generated, it is possible to guide the crane 180 to move along a straight line. A detailed configuration of the support 300 will be described later.

The transport unit 170 is a portion capable of transporting and loading articles and moving the articles in at least two axial directions. According to an embodiment, the transport unit 170 may be configured to move in the second direction (X direction in FIG. 1 to FIG. 3). For example, the transport unit 170 may be connected to the auxiliary rail 135 to be movable in the second direction along the auxiliary rail 135 provided on the base 130. In addition, it may be configured to be movable in a third direction (Z direction in FIG. 1 to FIG. 3) perpendicular to the first and second directions. For example, a part 160 (carriage) for transporting and loading articles may be moved up and down.

Referring to FIG. 3, the transport unit 170 may include a mover 140, a hoist 150, and a carriage 160.

The mover 140 may be movably connected to the auxiliary rail 135 provided on the base 130. The mover 140 may include a driving means (not illustrated) including a wheel and a motor, and may be moved along the auxiliary rail 135 through the driving means. For example, the mover 140 may move in the second direction (X direction in FIG. 1 to FIG. 3). Accordingly, an article may be transported in the second direction.

The hoist 150 is a portion that connects the mover 140 to the carriage 160, which will be described later. The hoist 150 may be connected such that the carriage 160 moves up and down with respect to the mover 140. For example, the hoist 150 may include an extensible guide rail, an actuator, and a hydraulic device. As another example, the hoist 150 may include a means for winding or unwinding ropes, wires, belts, and the like.

The carriage 160, which is a portion for loading or unloading articles, may include a space capable of accommodating articles. The carriage 160 may be moved up and down by the hoist 150 as described above. For example, the carriage 160 may move in the third direction (Z direction in FIG. 1 to FIG. 3) perpendicular to the first and second directions.

The crane 180 may move an article in three axial directions orthogonal to each other through movement of the base 130 in the first direction, movement of the mover 140 in the second direction, and movement of the carriage 160 in the third direction.

Hereinafter, the support 300 configured to guide the driving route of the crane 180 and to maintain straight driving will be described in detail.

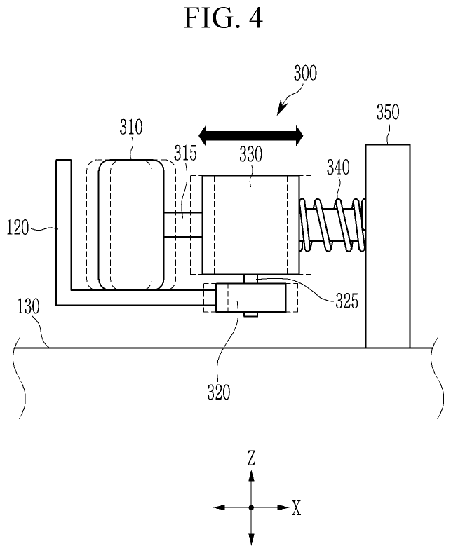

FIG. 4 illustrates an enlarged view of a portion B of FIG. 3. FIG. 4 schematically illustrates the support 300 for convenience of understanding.

According to an embodiment, the support 300 is connected to the base 130 and includes a guide wheel 320 configured to be pressed toward a first surface of the support rail 120 (surface with which a guide wheel contacts). The guide wheel 320 may be configured to be tilted. Accordingly, the guide wheel 320 may maintain contact with the support rail 120 in operation of the crane 180. For example, the guide wheel 320 may traverse any steps on the support rail 120 while maintaining contact with the support rail 120.

Referring to FIG. 4, the support 300 may include a support member 350, a bogie 330, an elastic member 340 and a guide wheel 320. The support 300 may further include a support wheel 310.

The support member 350 is a portion coupled to the base 130, and is a portion connecting components of the support 300 to the base 130.

The bogie 330 is a portion connected to the support member 350. The bogie 330 may be connected to the support member 350 through the elastic member 340. The elastic member 340 may apply a pressing force to the bogie 330 in a direction toward the support rail 120 (X direction in FIG. 4).

The guide wheel 320 may be rotatably connected to the bogie 330 about a rotation shaft 325. According to an embodiment, a pair of guide wheels 320 may be connected to the bogie 330. Since the bogie 330 is pushed toward the support rail 120 by the elastic member 340, the guide wheel 320 may be pushed toward the support rail 120. Accordingly, the guide wheel 320 may maintain contact with a contact surface of the support rail 120 (surface contacted by the guide wheel, e.g., surface perpendicular to the X direction) in operation of the crane 180.

The rotation shaft 325 of the guide wheel 320 may be arranged in a direction (Z direction) perpendicular to a direction (X direction) in which the guide wheel 320 is pressed. That is, the guide wheel 320 may rotate about an axis parallel to the third direction perpendicular to the first and second directions.

According to an embodiment, the support wheel 310 may be rotatably connected to the bogie 330 about a rotation shaft 315. The support wheel 310 may move along the support rail 120 on the support rail 120. The support wheel 310 may rotate while contacting a first surface of the support rail 120 without the need of its own driving means. In another embodiment, the support wheel 310 may have its own driving means, and may rotate by receiving a driving force from its own driving means.

The rotational shaft 315 of the support wheel 310 may be arranged in parallel with the rotational axis of the driving wheel 210 of the driver 200 (i.e., the X direction or in parallel with the second direction). The rotation shaft 315 of the support wheel 310 may be arranged perpendicular to the rotation shaft 325 of the guide wheel 320.

According to an embodiment, the guide wheel 320 may be connected to the bogie 330 to be tilted. Accordingly, it becomes easier to maintain the contact between the guide wheel 320 and the contact surface of the support rail 120. For example, a pair of guide wheels 320 may be tilted about at least one bogie axis provided in the bogie 330. As another example, each of the pair of guide wheels 320 may be tilted around a pair of bogie axes provided in the bogie 330. At least one bogie axis or the pair of bogie shafts may be parallel to each rotation shaft of the pair of guide wheels 320. Hereinafter, a shape of the support 300 according to various embodiments will be described.

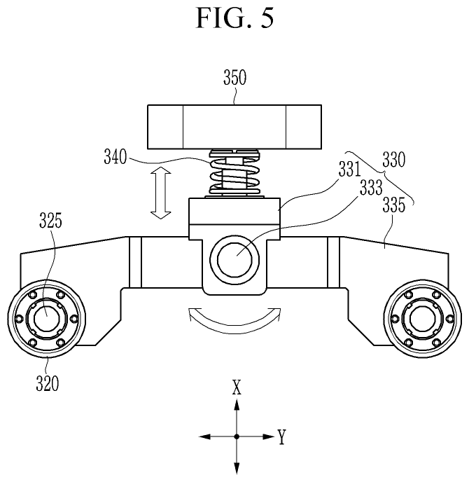

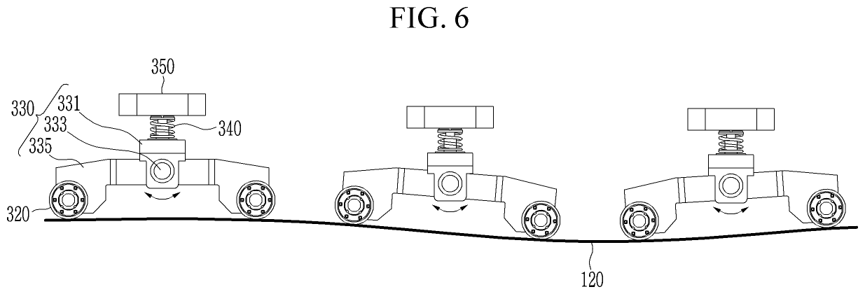

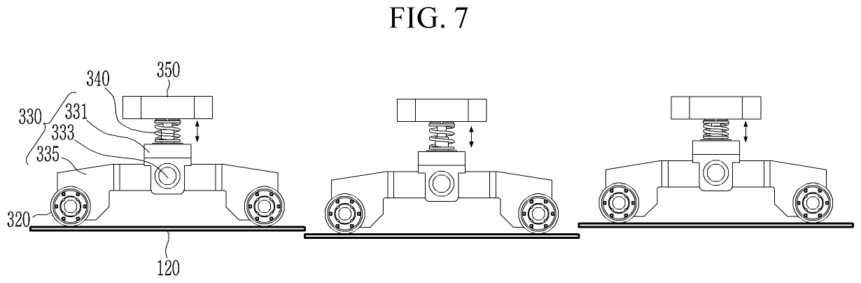

FIG. 5 illustrates a support in a crane of an overhead hoist transport system according to an embodiment, and FIG. 6 and FIG. 7 each illustrate a view for describing an operation of a support in a crane of an overhead hoist transport system according to an embodiment.

For convenience of understanding, in FIG. 5 to FIG. 7, the support is briefly illustrated except for some components (e.g., support wheels) of the support. For distinction from other embodiments, the shape of the support shown in FIG. 5 to FIG. 7 will be referred to as a first embodiment of the support.

Referring to FIG. 5, according to the first embodiment, the support 300 includes a support member 350, a bogie 330 connected to the support member 350, an elastic member 340 connecting the support member 350 to the bogie 330, and a pair of guide wheels 320 connected to the bogie 330.

In the present embodiment, the bogie 330 may include a bogie body 331, a bogie shaft 333, and a bogie link 335.

Referring to FIG. 5, the bogie 330 receives a pressing force by the elastic member 340 in the X direction and in a direction away from the support member 350. Accordingly, the pair of guide wheels 320 connected to the bogie 330 may be pressed toward the contact surface of the support rail 120 (see FIG. 3 and FIG. 4).

The bogie body 331 may be connected to the support member 350 through the elastic member 340. The bogie body 331 may include the bogie shaft 333 extending in a direction perpendicular to the X and Y directions (Z direction).

The bogie link 335 may be tiltably connected to the bogie body 331 through the bogie shaft 333. A central portion of the bogie link 335 may be connected to the bogie shaft 333. The bogie link 335 may have a shape extending from opposite sides of the bogie shaft 333. For example, it may have a structure symmetrical with respect to the bogie shaft 333. Opposite end portions of the bogie link 335 may be tilted about the bogie shaft 333 positioned at the center of the bogie link 335. Accordingly, a distance in the X direction from the bogie shaft 333 to the opposite end portions of the bogie link 335 may be adjusted.

The pair of guide wheels 320 may be rotatably supported at the opposite end portions of the bogie link 335.

Each of the pair of guide wheels 320 may rotate about the rotation shaft 325. The rotation shaft 325 of each guide wheel may be parallel to the bogie shaft 333. For example, the rotation shaft 325 of each guide wheel and the bogie shaft 333 may be parallel to the Z direction.

As described above, the bogie 330 may be pressed toward a contact surface of the support rail 120 by the elastic member 340. Accordingly, each guide wheel 320 may be pressed toward the contact surface (surface perpendicular to the X direction) of the support rail 120 by the elastic member 340.

As described above, the opposite end portions of the bogie link 335 may be tilted about the bogie shaft 333 positioned at the center of the bogie link 335. Accordingly, the pair of guide wheels 320 may be tilted about the bogie shaft 333 parallel to the rotational shaft 325 of each guide wheel 320.

In some embodiments, even when the linear support rail 120 is bent or a step is generated therein, the guide wheel 320 may maintain contact with the contact surface of the support rail 120 in operation of the crane 180.

Referring to FIG. 6, the straight support rail 120 may be bent and deformed. FIG. 6 illustrates the support 300 when the crane 180 moves along the deformed support rail 120. The pair of guide wheels 320 may be pressed toward the contact surface of the support rail 120 by the elastic member 340. The pair of guide wheels 320 may be tilted about the bogie shaft 333. Accordingly, when the pair of guide wheels 320 are moved along the support rail 120 having a curved form rather than a straight form, the pair of guide wheels 320 may move while maintaining contact with the contact surface of the support rail 120. That is, even when the support rail 120 is bent, the crane 180 may move straight.

Referring to FIG. 7, the support rail 120 may be configured by connecting a plurality of rail pieces, and a step may occur between the rail pieces. For example, the support rail 120 may not maintain a uniform straight shape due to an error in installation work or an error in a processing process, and may include steps.

Referring to FIG. 7, when the crane 180 is moved along the support rail 120 including a step, the pair of guide wheels 320 may be pressed toward the support rail 120 by the elastic member 340. Accordingly, when the pair of guide wheels 320 are moved along the support rail 120 with a step, the pair of guide wheels 320 may move while maintaining contact with the contact surface of the support rail 120. For example, when a distance difference (distance difference in the X direction) is generated by a step between the rail pieces, the aforementioned distance difference may be compensated for by a pressing force applied to the pair of guide wheels 320. That is, even when the support rail 120 includes a step, the crane 180 may move straight without losing contact with the contact surface of the support rail 120.

Hereinafter, various modifications of the support 300 will be described with reference to the drawings.

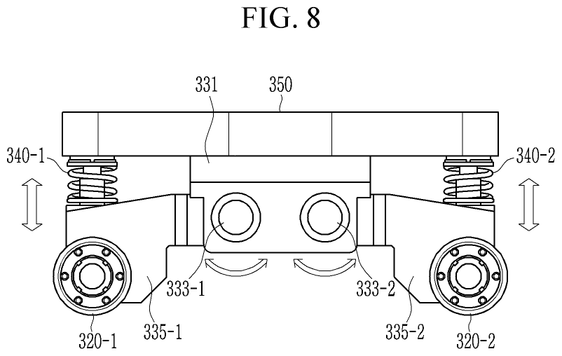

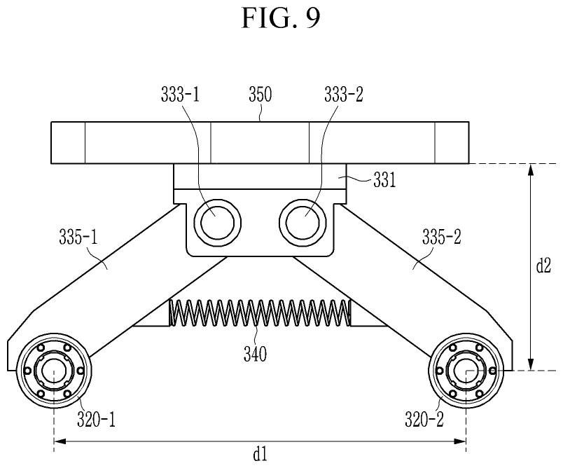

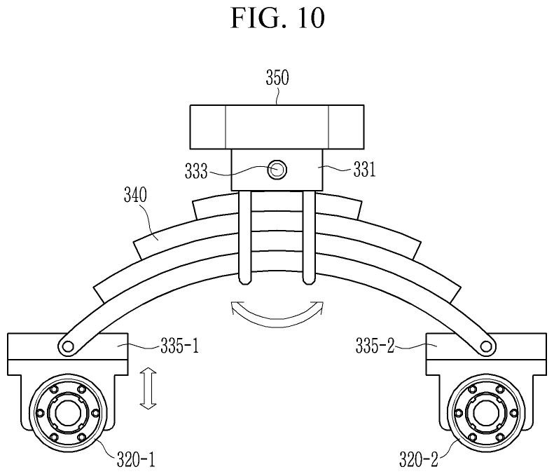

FIG. 8 to FIG. 10 illustrate various modifications of the support. Forms illustrated in FIG. 8, FIG. 9, and FIG. 10 will be respectively described by referring to second, third, and fourth embodiments for the support.

Referring to FIG. 8, the support 300 according to the second embodiment may include at least one bogie shaft 333-1 and/or 333-2. For convenience of understanding, a case including a pair of bogie shafts 333-1 and 333-2 will be described.

According to the second embodiment, the support 300 includes a support member 350, a bogie body 331, a pair of bogie shafts 333-1 and 333-2, a pair of bogie links 335-1 and 335-2, a pair of elastic members 340-1 and 340-2, and a pair of guide wheels 320-1 and 320-2. The pair of guide wheels 320-1 and 320-2 may be connected to the pair of bogie links 335-1 and 335-2, respectively.

In the present embodiment, the pair of bogie links 335-1 and 335-2 may be connected to the bogie body 331 so as to be tiltable about the pair of bogie shafts 333-1 and 333-2, respectively. The pair of bogie links 335-1 and 335-2 may be pressed toward the support rail 120 by the pair of elastic members 340-1 and 340-2, respectively.

In the present embodiment, the bogie body 331 may be fixedly coupled to the support member 350, and the pair of bogie links 335-1 and 335-2 may be connected to the support member 350 by the pair of elastic members 340-1 and 340-2, respectively.

Hereinafter, for convenience of understanding, a pair of components will be referred to as a first component and a second component, respectively.

A first end portion of the first bogie link 335-1 may be connected to the first bogie shaft 333-1, and the first guide wheel 320-1 may be connected to the second end portion of the first bogie link 335-1. A first end portion of the second bogie link 335-2 may be connected to the second bogie shaft 333-2, and the second guide wheel 320-2 may be connected to a second end portion of the second bogie link 335-2. At the second end portion of the first bogie link 335-1, the first elastic member 340-1 may be connected to an opposite side to which the first guide wheel 320-1 is connected. At the second end portion of the second bogie link 335-2, the second elastic member 340-2 may be connected to an opposite side to which the second guide wheel 320-2 is connected.

In the present embodiment, since the first and second guide wheels 320-1 and 320-2 are independently pressed and tilted, they may maintain contact with the support rail 120 more effectively.

Referring to FIG. 9, according to the third exemplary embodiment, the support 300 includes a support member 350, a bogie body 331, a pair of bogie shafts 333-1 and 333-2, a pair of bogie links 335-1 and 335-2, an elastic member 340 connecting the pair of bogie links 335-1 and 335-2 with each other, and a pair of guide wheels 320-1 and 320-2 respectively connected to the pair of bogie links 335-1 and 335-2.

In the present embodiment, the pair of bogie links 335-1 and 335-2 may be connected to the bogie body 331 so as to be tiltable about the pair of bogie shafts 333-1 and 333-2, respectively. For example, the first and second bogie links 335-1 and 335-2 may be arranged to form a predetermined angle of less than 180 degrees between the first and second bogie links 335-1 and 335-2. The elastic member 340 may be installed between the first and second bogie links 335-1 and 335-2.

A first end portion of the first bogie link 335-1 may be connected to the first bogie shaft 333-1, and the first guide wheel 320-1 may be connected to the second end portion. A first end portion of the second bogie link 335-2 may be connected to the second bogie shaft 333-2, and the second guide wheel 320-2 may be connected to a second end portion of the second bogie link 335-2.

The elastic member 340 may connect a central portion of the first bogie link 335-1 and a central portion of the second bogie link 335-2 with each other. The elastic member 340 may apply a pressing force so that the first bogie link 335-1 and the second bogie link 335-2 come closer (i.e., in a direction in which an angle between the first bogie link 335-1 and the second bogie link 335-2 becomes smaller).

Referring to FIG. 9, the elastic force of the elastic member 340 may tilt the first and second guide wheels 320-1 and 320-2 about the first and second bogie shafts 333-1 and 333-2, respectively. Accordingly, a distance d1 between the first and second guide wheels 320-1 and 320-2 may be reduced. A distance d2 from the support member 350 to the first and second guide wheels 320-1 and 320-2 may be increased. A pressing operation of the first and second guide wheels 320-1 and 320-2 to the support rail 120 and a tilting operation of the first and second guide wheels 320-1 and 320-2 may be interrelated with each other.

In the present embodiment, the first and second guide wheels 320-1 and 320-2 may be independently tilted, and may be pressed toward the support rail 120 in connection with the tilting operation. Accordingly, the first and second guide wheels 320-1 and 320-2 may maintain contact with the support rail 120 through a more efficient operating mechanism in operation of the crane 180.

Referring to FIG. 10, according to the fourth exemplary embodiment, the support 300 includes a support member 350, a bogie body 331, a bogie shaft 333, a pair of auxiliary members 335-1 and 335-2, an elastic member 340 connecting the bogie body 331 to each of the pair of auxiliary members 335-1 and 335-2, and a pair of guide wheels 320-1 and 320-2 respectively connected to the pair of auxiliary members 335-1 and 335-2.

In the present embodiment, the elastic member 340 may be configured to tilt about at least one bogie shaft 333. For example, the elastic member 340 may be connected to the bogie body 331 so as to be tiltable around one bogie shaft 333. As an example, the elastic member 340 may include a leaf spring.

Referring to FIG. 10, the central portion of the elastic member 340 may be connected to the bogie shaft 333. The elastic member 340 may be tilted about the bogie shaft 333. The first and second auxiliary members 335-1 and 335-2 may be connected to opposite end portions of the elastic member 340, respectively.

When the first and second auxiliary members 335-1 and 335-2 connected to the opposite end portions of the elastic member 340 are brought closer to the support member 350 by the elastic member 340, the first and second auxiliary members 335-1 and 335-2 may be pressed in a direction away from the support member 350.

The first guide wheel 320-1 may be connected to the first auxiliary member 335-1. The second guide wheel 320-2 may be connected to the second auxiliary member 335-2.

Accordingly, the first and second guide wheels 320-1 and 320-2 may each be pressed in a direction toward a contact surface of the support rail 120 by the elastic force of the elastic member 340.

In the present embodiment, the elastic member 340 may include a leaf spring. A central portion of the elastic member 340 including the leaf spring may be tilted about the bogie shaft 333. The first and second guide wheels 320-1 and 320-2 connected to opposite ends of the elastic member 340 may be pressed toward the support rail 120. Accordingly, the first and second guide wheels 320-1 and 320-2 may maintain contact with the support rail 120 by using a structure of the leaf spring itself in operation of the crane 180.

In the various embodiments as described above, the guide wheel 320 may be configured to be pressed toward the contact surface of the support rail 120, and may be configured to be tilted about the bogie shaft 333 parallel to the rotation shaft 325 of the guide wheel 320. Accordingly, even when the support rail 120 is deformed or stepped, the guide wheel 320 may maintain contact with the support rail 120 in operation of the crane 180.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. An overhead hoist transport system comprising:
a driving rail extending in a first direction;
a pair of support rails extending in the first direction and being spaced apart from each other in a second direction perpendicular to the first direction, wherein the driving rail is disposed in a space between the pair of support rails; and
a crane movably connected to the driving rail and the support rail and configured to move along the driving rail and the support rail,
wherein the crane includes:
a base extending lengthwise in the second direction and crossing the driving rail and the pair of support rails;
a driving wheel connected to the base and configured to move along the driving rail; and
a pair of guide wheels connected to the base and configured to be pressed toward contact surfaces of the pair of support rails using an elastic force,
wherein the pair of guide wheels contact the pair of support rails by the elastic force, and
wherein the contact surfaces are surfaces contacting the pair of guide wheels.

2. The overhead hoist transport system of claim 1,
wherein the crane further includes:
a support member connected to the base;
a bogie body including a bogie shaft and connected to the support member;
an elastic member connecting the support member and the bogie body with each other; and
a bogie link having a central portion connected to the bogie body and configured to be tiltable about a bogie axis, wherein the bogie axis corresponds to a lengthwise direction of the bogie shaft,
wherein the pair of guide wheels are rotatably supported at opposite ends of the bogie link, respectively, and
wherein the elastic member is configured to:
press the bogie body in a direction toward the pair of support rails; and
press the pair of guide wheels to contact the contact surfaces of the pair of support rails.

3. The overhead hoist transport system of claim 1,
wherein the crane further includes:
a support member coupled to the base;
a bogie body including a pair of bogie shafts extending parallel to each other and connected to the support member;
a pair of bogie links connected to the bogie body and configured to be tiltable around the pair of bogie shafts, respectively; and
a pair of elastic members including a first elastic member connecting the support member to one of the pair of bogie links, and a second elastic member connecting the support member to the other of the pair of bogie links,
wherein the pair of guide wheels are rotatably supported on the pair of bogie links, respectively, and
wherein the pair of elastic members are configured to:
press the pair of bogie links in a direction toward the pair of support rails; and
press the pair of guide wheels to contact the contact surfaces of the pair of support rails.

4. The overhead hoist transport system of claim 1,
wherein the crane further includes:
a support member connected to the base;
a bogie body including a pair of bogie shafts extending parallel to each other and connected to the support member;
a pair of bogie links connected to the bogie body and configured to be tiltable around the pair of bogie shafts, respectively; and
an elastic member connecting the pair of bogie links with each other,
wherein the pair of guide wheels are rotatably supported on the pair of bogie links, respectively, and
wherein the elastic member is configured to:
apply a pressing force in a direction in which the pair of bogie links come closer with each other; and
press the pair of guide wheels to contact the pair of support rails.

5. The overhead hoist transport system of claim 1,
wherein the crane includes:
a support member connected to the base;
a bogie body including a bogie shaft and connected to the support member;
an elastic member including a central portion connected to the bogie body and configured to be tiltable around a bogie axis, wherein the bogie axis corresponds to a lengthwise direction of the bogie shaft, and wherein the elastic member includes a plate spring; and
a pair of auxiliary members connected to opposite end portions of the elastic member,
wherein the pair of guide wheels are rotatably supported on the pair of auxiliary members, respectively, and
wherein the pair of elastic members are configured to:
press the pair of auxiliary members in a direction toward the pair of support rails; and
press the pair of guide wheels to contact the contact surfaces of the pair of support rails.

6. The overhead hoist transport system of claim 1,
wherein the crane further includes:
a pair of support wheels configured to move along the pair of support rails.

7. The overhead hoist transport system of claim 6,
wherein a rotation shaft of each of the pair of guide wheels extends lengthwise in a direction perpendicular to an axis of rotation of each of the pair of support wheels.

8. The overhead hoist transport system of claim 1,
wherein the base includes an auxiliary rail extending in the second direction, and
wherein the crane further includes a transport unit movably connected to the auxiliary rail and configured to move along the auxiliary rail.

9. The overhead hoist transport system of claim 8,
wherein the transport unit includes:
a mover movably connected to the auxiliary rail;
a carriage configured to load and unload goods; and
a hoist connecting the mover and the carriage with each other so that the mover moves up or down the carriage using the hoist.

10. An overhead hoist transport system comprising:
a driving rail extending in a first direction;
a pair of support rails extending in the first direction and being spaced apart from each other in a second direction perpendicular to the first direction, wherein the driving rail is disposed in a space between the pair of support rails; and
a crane movably connected to the driving rail and the support rail and configured to move along the driving rail and the support rail,
wherein the crane includes:
a base extending lengthwise in the second direction and crossing the driving rail and the pair of support rails;
a driving wheel connected to the base and configured to move along the driving rail;
a bogie including at least one bogie shaft, wherein the bogie is configured to tilt about the at least one bogie shaft; and
a support connected to the base and the bogie and configured to tilt about the at least one bogie shaft,
wherein the support includes a pair of guide wheels configured to move along the pair of support rails, and
wherein the pair of guide wheels are configured to be pressed toward the pair of support rails to maintain contact between the pair of support rails and the pair of guide wheels.

11. The overhead hoist transport system of claim 10,
wherein the at least one bogie shaft is parallel to a rotation shaft of each of the pair of guide wheels.

12. The overhead hoist transport system of claim 10,
wherein the support further includes:
a support member connected to the base; and
an elastic member connecting the support member to the bogie.

13. The overhead hoist transport system of claim 10,
wherein the at least one bogie shaft includes a first bogie shaft and a second bogie shaft, and
wherein the pair of guide wheels are connected to the bogie and are configured to be tiltable about the first bogie shaft and the second bogie shaft, respectively.

14. The overhead hoist transport system of claim 13,
wherein the support further includes a first bogie link and a second bogie link connecting the pair of guide wheels to the first bogie shaft and the second bogie shaft, respectively, and
wherein the pair of guide wheels are rotatably supported by the first bogie link and the second bogie link, respectively.

15. The overhead hoist transport system of claim 14,
wherein the support further includes:
a support member connected to the base; and
a pair of elastic members including a first elastic member connecting the support member to the first bogie link, and a second elastic member connecting the support member to the second bogie link.

16. The overhead hoist transport system of claim 14,
wherein the support further includes an elastic member connecting the first bogie link to the second bogie link.

17. The overhead hoist transport system of claim 10,
wherein the support further includes an elastic member connecting the bogie to each of the pair of guide wheels,
wherein the elastic member is configured to be tiltable about the at least one bogie shaft, and
wherein the elastic member includes a leaf spring.

18. The overhead hoist transport system of claim 10,
wherein the support further includes a pair of support wheels on the pair of support rails, respectively,
wherein each of the support wheels is configured to rotate about an axis parallel to the second direction, and
wherein each of the pair of guide wheels rotates about an axis parallel to a third direction perpendicular to the first direction and the second direction.

19. The overhead hoist transport system of claim 10,
wherein the base includes an auxiliary rail extending in the second direction, and
wherein the crane includes a carriage configured to:
load and unload articles;
move along the auxiliary rail; and
move along a third direction perpendicular to the first and second directions.

20. An overhead hoist transport system comprising:
first and second support rails provided along a ceiling in a factory and extending parallel to each other in a first direction;
a driving rail positioned between the first support rail and the second support rail; and
a crane movably connected to the first support rail, the second support rail, and the driving rail to move along the first support rail, the second support rail, and the driving rail,
wherein the crane includes:
a base extending lengthwise in a second direction perpendicular to the first direction and crossing the first support rail, the second support rail, and the driving rail, wherein the base includes an auxiliary rail extending in the second direction;
a carriage movably connected to the auxiliary rail and configured to move in a third direction perpendicular to the first and second directions;
a driving wheel connected to the base and configured to move along the driving rail; and
a support including:
a bogie including at least one bogie shaft and connected to the base; and
a pair of guide wheels connected to the bogie and configured to be tiltable about the at least one bogie shaft and to move along the first support rail and the second support rail, respectively, and
wherein the pair of guide wheels are configured to be pressed toward the first support rail and the second support rail to maintain contact with the first support rail and the second support rail, respectively.
